(19) United States
(12) Patent Application Publication
(10) Pub. No.: US 2021/0241708 A1
(43) Pub. Date: Aug. 5, 2021

(54) SHIFT REGISTER AND DRIVING METHOD THEREFOR, GATE DRIVER CIRCUIT, AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Xun PU, Beijing (CN); Junhui WU, Beijing (CN); Jiandong GUO, Beijing (CN)

(21) Appl. No.: 17/051,722

(22) PCT Filed: Jan. 13, 2020
(86) PCT No.: PCT/CN2020/071815

§ 371 Date: Oct. 29, 2020

(30) Foreign Application Priority Data
Jan. 18, 2019 (CN) 201910049433.9

(51) Int. Cl. G09G 3/36; G09G 3/3266; G11C 19/28

(52) U.S. Cl. CPC G09G 3/3677; G09G 2310/0286; G11C 19/28; G09G 3/3266

(57) ABSTRACT

A shift register includes a pull-up node, an output control sub-circuit, a first energy storage sub-circuit and an output sub-circuit. The output control sub-circuit is coupled to the pull-up node, a first clock signal terminal and the first energy storage sub-circuit, and is configured to transmit a first clock signal to the first energy storage sub-circuit under control of a voltage of the pull-up node. The first energy storage sub-circuit is coupled to the pull-up node and the output control sub-circuit, and is configured to store the voltage of the pull-up node, and boost the voltage of the pull-up node under action of the first clock signal. The output sub-circuit is coupled to the pull-up node and a signal output terminal, and is configured to transmit the boosted voltage of the pull-up node to the signal output terminal under the control of the voltage of the pull-up node.

### CROSS-REFERENCE TO RELATED APPLICATIONS

This application is a national phase entry under 35 USC 371 of International Patent Application No. PCT/CN2020/071815 filed on Jan. 13, 2020, which claims priority to Chinese Patent Application No. 201910049433.9, filed on Jan. 18, 2019, which are incorporated herein by reference in their entirety.

### TECHNICAL FIELD

The present disclosure relates to the field of display technologies, and in particular, to a shift register and a driving method therefor, a gate driver circuit, and a display device.

### BACKGROUND

Gate driver on array (GOA) is a technology that integrates a gate driver circuit on an array substrate. Each stage of a GOA circuit (i.e., a shift register) is electrically connected to a gate line and is configured to output a gate scanning signal to the gate line, thereby achieving progressive scanning (driving) of a plurality of gate lines in a display device.

### SUMMARY

In one aspect, a shift register is provided. The shift register includes a pull-up node, an output control sub-circuit, a first energy storage sub-circuit and an output sub-circuit. The output control sub-circuit is coupled to the pull-up node, a first dock signal terminal and the first energy storage sub-circuit; and the output control sub-circuit is configured to transmit a first clock signal received at the first clock signal terminal to the first energy storage sub-circuit under control of a voltage of the pull-up node. The first energy storage sub-circuit is coupled to the pull-up node and the output control sub-circuit; and the first energy storage sub-circuit is configured to store the voltage of the pull-up node, and boosts the voltage of the pull-up node under action of the first clock signal. The output sub-circuit is coupled to the pull-up node and a signal output terminal; and the output sub-circuit is configured to transmit the boosted voltage of the pull-up node to the signal output terminal under the control of the voltage of the pull-up node.

In some embodiments, the output control sub-circuit includes a first transistor, a control electrode of the first transistor is coupled to the pull-up node, a first electrode of the first transistor is coupled to the first clock signal terminal, and a second electrode of the first transistor is coupled to the first energy storage sub-circuit. The first energy storage sub-circuit includes a first capacitor, a first terminal of the first capacitor is coupled to the pull-up node, and a second terminal of the first capacitor is coupled to the second electrode of the first transistor. The output sub-circuit includes a second transistor, a control electrode of the second transistor is coupled to the pull-up node, a first electrode of the second transistor is coupled to the pull-up node, and a second electrode of the second transistor is coupled to the signal output terminal.

In some embodiments, the shift register further includes a pull-down sub-circuit. The pull-down sub-circuit is coupled to a second clock signal terminal, the signal output terminal and a first voltage terminal, and is configured to transmit a first voltage signal received at the first voltage terminal to the signal output terminal in response to a second clock signal received at the second clock signal terminal.

In some embodiments, the pull-down sub-circuit includes a third transistor, a control electrode of the third transistor is coupled to the second clock signal terminal, a first electrode of the third transistor is coupled to the first voltage terminal, and a second electrode of the third transistor is coupled to the signal output terminal.

In some embodiments, the shift register further includes a second energy storage sub-circuit. The second energy storage sub-circuit is coupled between the first energy storage sub-circuit and the signal output terminal, and is configured to keep the voltage of the pull-up node stable in a process of transmitting the boosted voltage of the pull-up node to the signal output terminal.

In some embodiments, the second energy storage sub-circuit includes a second capacitor, and a first terminal of the second capacitor is coupled to the signal output terminal. In a case where the first energy storage sub-circuit includes a first capacitor, a second terminal of the second capacitor is coupled to the first energy storage sub-circuit.

In some embodiments, the shift register further includes an input sub-circuit and a reset sub-circuit. The input sub-circuit is coupled to a signal input terminal, a second voltage terminal and the pull-up node, and is configured to transmit a second voltage signal received at the second voltage terminal to the pull-up node in response to an input signal received at the signal input terminal. The reset sub-circuit is coupled to a reset signal terminal, a first voltage terminal and the pull-up node, and is configured to transmit a first voltage signal received at the first voltage terminal to the pull-up node in response to a reset signal received at the reset signal terminal.

In some embodiments, the input sub-circuit includes a fourth transistor. A control electrode of the fourth transistor is coupled to the signal input terminal, a first electrode of the fourth transistor is coupled to the second voltage terminal, and a second electrode of the fourth transistor is coupled to the pull-up node. The reset sub-circuit includes a fifth transistor. A control electrode of the fifth transistor is coupled to the reset signal terminal, a first electrode of the fifth transistor is coupled to the first voltage terminal, and a second electrode of the fifth transistor is coupled to the pull-up node.

In some embodiments, the shift register further includes a pull-down node, a node control sub-circuit, a first noise reduction sub-circuit and a second noise reduction sub-circuit. The node control sub-circuit is coupled to the second voltage terminal, the pull-up node, the first voltage terminal and the pull-down node. The node control sub-circuit is configured to transmit the first voltage signal received at the first voltage terminal to the pull-down node in response to the voltage of the pull-up node and the second voltage signal received at the second voltage terminal; and to transmit the second voltage signal received at the second voltage terminal to the pull-down node in response to the voltage of the pull-up node and the second voltage signal received at the second voltage terminal. The first noise reduction sub-circuit is coupled to the pull-up node, the pull-down node and the first voltage terminal, and is configured to transmit the first voltage signal received at the first voltage terminal to the pull-up node under control of a voltage of the pull-down node. The second noise reduction sub-circuit is coupled to the pull-down node, the first voltage terminal and the signal output terminal, and is configured to transmit the first voltage signal received at the first voltage terminal to the signal output terminal under the control of the voltage of the pull-down node.

In some embodiments, the node control sub-circuit includes a sixth transistor and a seventh transistor. A control electrode of the sixth transistor is coupled to the second voltage terminal, a first electrode of the sixth transistor is coupled to the second voltage terminal, and a second electrode of the sixth transistor is coupled to the pull-down node; a control electrode of the seventh transistor is coupled to the pull-up node, a first electrode of the seventh transistor is coupled to the first voltage terminal, and a second electrode of the seventh transistor is coupled to the pull-down node. The first noise reduction sub-circuit includes an eighth transistor. A control electrode of the eighth transistor is coupled to the pull-down node, a first electrode of the eighth transistor is coupled to the first voltage terminal, and a second electrode of the eighth transistor is coupled to the pull-up node. The second noise reduction sub-circuit includes a ninth transistor. A control electrode of the ninth transistor is coupled to the pull-down node, a first electrode of the ninth transistor is coupled to the first voltage terminal, and a second electrode of the ninth transistor is coupled to the signal output terminal.

In some embodiments, a size of the seventh transistor is greater than a size of the sixth transistor.

In some embodiments, the shift register further includes a pull-down sub-circuit, an input sub-circuit, a reset sub-circuit, a pull-down node, a node control sub-circuit, a first noise reduction sub-circuit and a second noise reduction sub-circuit. The output control sub-circuit includes a first transistor, the first energy storage sub-circuit includes a first capacitor, the output sub-circuit includes a second transistor, the pull-down sub-circuit includes a third sub-circuit, the input sub-circuit includes a fourth transistor, the reset sub-circuit includes a fifth transistor, the node control sub-circuit includes a sixth transistor and a seventh transistor, the first noise reduction sub-circuit includes an eighth transistor, and the second noise reduction sub-circuit includes a ninth transistor.

A control electrode of the first transistor is coupled to the pull-up node, a first electrode of the first transistor is coupled to the first clock signal terminal, and a second terminal of the first transistor is coupled to a second terminal of the first capacitor. A first terminal of the first capacitor is coupled to the pull-up node, and is further coupled to the control electrode of the first transistor. a control electrode of the second transistor is coupled to the pull-up node, A first electrode of the second transistor is coupled to the pull-up node, and a second electrode of the second transistor is coupled to the signal output terminal. A control electrode of the third transistor is coupled to a second clock signal terminal, a first electrode of the third transistor is coupled to a first voltage terminal, and a second electrode of the third transistor is coupled to the signal output terminal. A control electrode of the fourth transistor is coupled to a signal input terminal, a first electrode of the fourth transistor is coupled to a second voltage terminal, and a second electrode of the fourth transistor is coupled to the pull-up node. A control electrode of the fifth transistor is coupled to a reset signal terminal, a first electrode of the fifth transistor is coupled to the first voltage terminal, and a second electrode of the fifth transistor is coupled to the pull-up node.

A control electrode of the sixth transistor is coupled to the second voltage terminal, a first electrode of the sixth transistor is coupled to the second voltage terminal, and a second electrode of the sixth transistor is coupled to the pull-down node. A control electrode of the seventh transistor is coupled to the pull-up node, a first electrode of the seventh transistor is coupled to the first voltage terminal, and a second electrode of the seventh transistor is coupled to the pull-down node. A control electrode of the eighth transistor is coupled to the pull-down node, a first electrode of the eighth transistor is coupled to the first voltage terminal, and a second electrode of the eighth transistor is coupled to the pull-up node. A control electrode of the ninth transistor is coupled to the pull-down node, a first electrode of the ninth transistor is coupled to the first voltage terminal, and a second electrode of the ninth transistor is coupled to the signal output terminal.

In another aspect, agate driver circuit is provided. The gate driver circuit includes at least two cascaded shift registers as described in the above aspect. A signal input terminal of a first stage shift register is coupled to a start signal terminal. A signal input terminal of any stage shift register other than the first stage shift register is coupled to a signal output terminal of a previous stage shift register of the any stage shift register. A reset signal terminal of any stage shift register other than a last stage shift register is coupled to a signal output terminal of a next stage shift register of this any stage shift register. A reset signal terminal of the last stage shift register is coupled to a separately provided signal terminal for outputting a reset signal, or is coupled to the start signal terminal.

In yet another aspect, a display device is provided. The display device includes the gate driver circuit as described above.

In yet another aspect, a driving method for a shift register is provided, which is applied to the shift register as described above. The driving method includes a frame cycle including a charging period and an outputting period.

The charging period includes: the output control sub-circuit being turned on under the control of the voltage of the pull-up node, to transmit the first clock signal received at the first clock signal terminal to the first energy storage sub-circuit; and the first energy storage sub-circuit storing the voltage at the pull-up node.

The outputting period includes: the output control sub-circuit being turned on under the control of the voltage of the pull-up node, to transmit the first clock signal to the first energy storage sub-circuit; the first energy storage sub-circuit boosting the voltage of the pull-up node in response to the first clock signal; and the output sub-circuit transmitting the boosted voltage of the pull-up node to the signal output terminal under the control of the voltage of the pull-up node.

In some embodiments, in a case where the shift register further includes a pull-down sub-circuit, the charging period further includes: the pull-down sub-circuit being turned on under the control of a second clock signal transmitted by a second clock signal terminal, to transmit a first voltage signal received at a first voltage terminal to the signal output terminal.

In some embodiments, in a case where the shift register further includes a second energy storage sub-circuit, the outputting period further includes: the second energy storage sub-circuit keeping the voltage of the pull-up node stable in a process of transmitting the boosted voltage of the pull-up node to the signal output terminal.

In some embodiments, in a case where the shift register further includes the pull-down node, an input sub-circuit, a reset sub-circuit, a node control sub-circuit, a first noise reduction sub-circuit and a second noise reduction sub-circuit, the charging period further includes: the input sub-circuit being turned on under the control of an input signal transmitted by a signal input terminal, to transmit a second voltage signal received at a second voltage terminal to the pull-up node; and the node control sub-circuit transmitting the first voltage signal received at the first voltage terminal to the pull-down node in response to the voltage of the pull-up node and the second voltage signal received at the second voltage terminal.

The driving method further includes a resetting period after the outputting period. The resetting period includes: the reset sub-circuit being turned on under control of a reset signal transmitted by a reset signal terminal, to output the first voltage signal received at the first voltage terminal to the pull-up node; the node control sub-circuit transmitting the second voltage signal received at the second voltage terminal to the pull-down node in response to the voltage of the pull-up node and the second voltage signal received at the second voltage terminal; the first noise reduction sub-circuit being turned on under the control of the voltage of the pull-down node, to transmit the first voltage signal received at the first voltage terminal to the pull-up node; the second noise reduction sub-circuit being turned on under the control of the voltage of the pull-down node, to transmit the first voltage signal received at the first voltage terminal to the signal output terminal; and the pull-down sub-circuit being turned on under the control of the second clock signal transmitted by the second clock signal terminal, to transmit the first voltage signal received at the first voltage terminal to the signal output terminal.

The driving method further includes a noise reduction period after the resetting period and before a next frame cycle. The noise reduction period includes: the second noise reduction sub-circuit being kept on under the control of the voltage of the pull-down node, to transmit the first voltage signal received at the first voltage terminal to the signal output terminal.

### BRIEF DESCRIPTION OF THE DRAWINGS

In order to describe technical solutions in the present disclosure more clearly, accompanying drawings to be used in some embodiments of the present disclosure will be introduced briefly. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, and are not limitations on actual sizes of products, an actual process of a method and actual timings of signals to which the embodiments of the present disclosure relate.

FIG. is a diagram showing a structure of a shift register, in accordance with the related art;

FIG. 2 is a diagram showing a structure of a shift register, in accordance with some embodiments of the present disclosure;

FIG. 3 is a diagram showing a structure of another shift register, in accordance with some embodiments of the present disclosure;

FIG. 4 is a diagram showing a structure of yet another shift register, in accordance with some embodiments of the present disclosure;

FIG. 5 is a diagram showing a structure of yet another shift register, in accordance with some embodiments of the present disclosure;

FIG. 6 is a diagram showing a structure of a gate driver circuit, in accordance with some embodiments of the present disclosure;

FIG. 7 is a timing diagram of a driving method for a shift register, in accordance with some embodiments of the present disclosure;

FIG. 8 is a flow diagram of a driving method for a shift register, in accordance with some embodiments of the present disclosure; and

FIG. 9 is a timing diagram of another driving method for a shift register, in accordance with some embodiments of the present disclosure.

### DETAILED DESCRIPTION

Technical solutions in some embodiments of the present disclosure will be described clearly and completely in combination with accompanying drawings. Obviously, the described embodiments are merely some but not all embodiments of the present disclosure. All other embodiments obtained on a basis of the embodiments of the present disclosure by a person of ordinary skill in the art shall be included in the protection scope of the present disclosure.

Unless the context requires otherwise, throughout the specification and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials or characteristics may be included in any one or more embodiments or examples in any suitable manner.

Terms such as “first” and “second” are only used for descriptive purposes and are not to be construed as indicating or implying the relative importance or implicitly indicating the number of indicated technical features below. Thus, features defined by the terms “first” and “second” may explicitly or implicitly include one or more of the features. In the description of the embodiments of the present disclosure, term “plurality” means two or more unless otherwise specified.

Some embodiments may be described using the expression “coupled” and “connected” along with their derivatives. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. The term “coupled” or “communicatively coupled”, however, may also mean that two or more elements are not in direct contact with each other, but yet still cooperate or interact with each other. The embodiments disclosed herein are not necessarily limited to this context.

Unless otherwise defined, technical terms or scientific terms used in the embodiments of the present disclosure shall be understood as ordinary meanings by a person of ordinary skill in the field that the present disclosure belongs to. The terms “first”, “second” and the like used in the embodiments of the present disclosure are not intended to mean any order, quantity or importance, and are merely used to distinguish different components. A word such as “include” or “comprise” means that an element or item appearing before the word covers the element(s) or item(s) appearing after the word and the equivalent thereof without excluding other elements or items. A word “connect”. “couple” or a similar word thereof is not limited to physical or mechanical connections, but may include electrical connections, whether direct or indirect. “Upper” “lower” “left”, “right”, etc. are only used to indicate a relative positional relationship, and when the absolute position of the described object is changed, the relative positional relationship may also be changed accordingly.

In a display device, a GOA circuit includes a plurality of shift registers. Each stage of the GOA circuit (i.e., a shift register) is electrically connected to a gate line, that is, the number of shift registers included in the GOA circuit is equivalent to the resolution of the display device. Each shift register is configured to provide a scanning signal to the gate line electrically connected thereto, thereby achieving progressive scanning (driving) of a plurality of gate lines in a display panel. Each gate line corresponds to a row of sub-pixels. Under control of the scanning signal, switching transistors in pixel driver circuits corresponding to respective sub-pixels in the row of sub-pixels are turned on, so as to receive data signals transmitted by data lines and charge the sub-pixels.

In the related art, as shown in FIG. 1, a shift register includes a pull-up node PU and a pull-down node PD. Generally, in a same period, potentials at the pull-up node PU and the pull-down node PD are opposite. By controlling the potentials at the pull-up node PU and the pull-down node PD, a signal output terminal Output is controlled to output a scanning signal or stop outputting a scanning signal.

For example, in an outputting period of the scanning signal, the potential at the pull-up node PU is a high potential, and the potential at the pull-down node PD is a low potential. A transistor M3 is turned on under the control of the pull-up node PU, and a clock signal clk received at a dock signal terminal CLK (in this period, the clock signal clk is at a high level) is output as a scanning signal through the signal output terminal Output.

That is, in the related art, the high level of the clock signal clk (for example, 22V) is output as the scanning signal to the signal output terminal Output. However, with popularity of high-resolution and large-size display devices, charging time of each row of sub-pixels becomes less and less, which may cause insufficient sub-pixel charging. In general, the higher the gate voltage of the switching transistor in the pixel driver circuit is, the greater the conduction degree of the switching transistor is, and the more the sub-pixel is charged. The problem may be solved by increasing the voltage of the scanning signal to improve a charging rate of the sub-pixel. For example, the high level of the clock signal clk is increased (for example, the high level may be increased from 22V to 30V). However, in this way, power consumption of the display device will be greatly increased, which is inconsistent with the current concept of low power consumption.

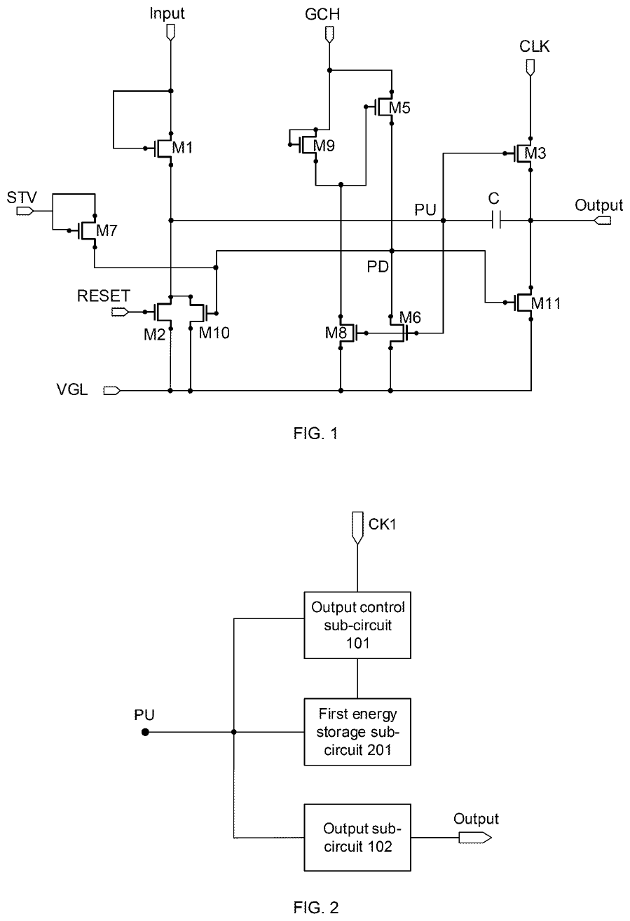

On this basis, some embodiments of the present disclosure provide a shift register (or a gate driver circuit) with low power consumption and high output voltage. As shown in FIGS. 2 to 5, the shift register includes a pull-up node PU, an output control sub-circuit 101, a first energy storage sub-circuit 201 and an output sub-circuit 102.

The output control sub-circuit 101 is coupled to the pull-up node PU, a first clock signal terminal CK1 and the first energy storage sub-circuit 201. The output control sub-circuit 101 is configured to transmit a first dock signal ck1 received at the first clock signal terminal CK1 to the first energy storage sub-circuit 201 under control of a voltage of the pull-up node. The first clock signal terminal CK1 is configured to receive the first clock signal ck1 and transmit the first clock signal ck1 to the output control sub-circuit 101.

The first energy storage sub-circuit 201 is coupled to the pull-up node PU and the output control sub-circuit 101. The first energy storage sub-circuit 201 is configured to store the voltage of the pull-up node PU and boost the voltage of the pull-up node PU under action of the first clock signal ck1.

The output sub-circuit 102 is coupled to the pull-up node PU and a signal output terminal Output. The output sub-circuit 102 is configured to transmit the boosted voltage of the pull-up node PU to the signal output terminal Output under control of the voltage of the pull-up node PU.

In the shift register provided by some embodiments of the present disclosure, the output sub-circuit 102 is coupled to the pull-up node PU and the signal output terminal Output, so that the output sub-circuit 102 may directly output the voltage of the pull-up node PU to the signal output terminal Output under the control of the voltage of the pull-up node PU. Therefore, a voltage transmitted to the signal output terminal Output is the voltage of the pull-up node PU, rather than a high level of the clock signal clk transmitted to the signal output terminal Output in the related art. And on this basis, in the shift register provided in some embodiments of the present disclosure, in the charging period, the low level of the first clock signal ck1 is transmitted to the first energy storage sub-circuit 201 through the output control sub-circuit 101, and the voltage of the pull-up node PU is stored by the first energy storage sub-circuit 201. In the outputting period, the high level of the first clock signal ck1 is transmitted to the first energy storage sub-circuit 201 through the output control sub-circuit 101, so that the first energy storage sub-circuit 201 boosts the voltage of the pull-up node PU under the action of the first clock signal ck1, and the voltage of the boosted pull-up node PU is transmitted to the signal output terminal Output through the output sub-circuit 102, that is, the voltage of the boosted pull-up node PU is used as a scanning signal.

It will be seen that, compared with the related art in which a high level signal of a clock signal terminal CK1 is transmitted as a scanning signal through a signal output terminal Output (for example, the high level signal (i.e., the scanning signal) from the clock signal terminal substantially has the same potential as the pull-up node PU in the shift register provided in some embodiments of the present disclosure in the charging period), the shift register in the present disclosure may boost the voltage of the pull-up node PU under the action of the first clock signal ck1, and may output the boosted voltage of the pull-up node PU as the scanning signal to the signal output terminal Output. Therefore, the voltage of the scanning signal output by the shift register provided in some embodiments of the present disclosure is higher than the voltage of the scanning signal (the high level of the clock signal) output by the shift register in the related art. In this way, the voltage of the scanning signal may be increased without increasing the high level of the clock signal clk and the power consumption of the display device, so that a charging rate of the sub-pixel is improved, which is more conducive to the application of the gate driver circuit in display devices with high-resolution and large-size. In addition, in a case where the display device to which the shift register is applied has a certain resolution, since the voltage of the scanning signal may be increased, the charging rate of the sub-pixel is ensured. As a result, a size of a transistor included in the pixel driver circuit in the sub-pixel may be reduced, for example, a width-to-length ratio of the transistor may be reduced, which may increase an aperture ratio of the sub-pixel and improve the display effect.

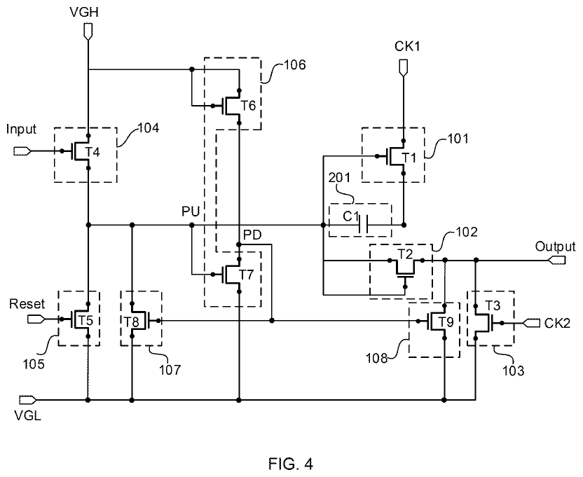

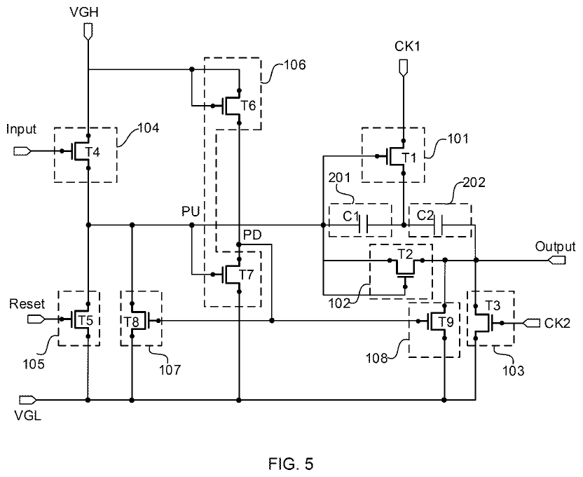

For example, as shown in FIGS. 4 and 5, the output control sub-circuit 101 includes a first transistor T1. A control electrode of the first transistor T1 is coupled to the pull-up node PU, and a first electrode of the first transistor T1 is coupled to the first clock signal terminal CK1, and a second electrode of the first transistor T1 is coupled to the first energy storage sub-circuit 201. The first transistor T1 is configured to be turned on under the control of the voltage of the pull-up node, to transmit the first dock signal ck1 received at the first clock signal terminal CK1 to the first energy storage sub-circuit 201.

The first energy storage sub-circuit 201 includes a first capacitor C1. A first terminal of the first capacitor C1 is coupled to the pull-up node PU, and a second terminal of the first capacitor C1 is coupled to the second electrode of the first transistor T1. The first capacitor C1 is configured to store the voltage of the pull-up node PU.

The output sub-circuit 102 includes a second transistor T2. A control electrode of the second transistor T2 is coupled to the pull-up node PU, a first electrode of the second transistor T2 is coupled to the pull-up node PU, and a second electrode of the second transistor T2 is coupled to the signal output terminal Output. The second transistor T2 is configured to be turned on under the control of the voltage of the pull-up node to transmit the boosted voltage of the pull-up node PU to the signal output terminal Output.

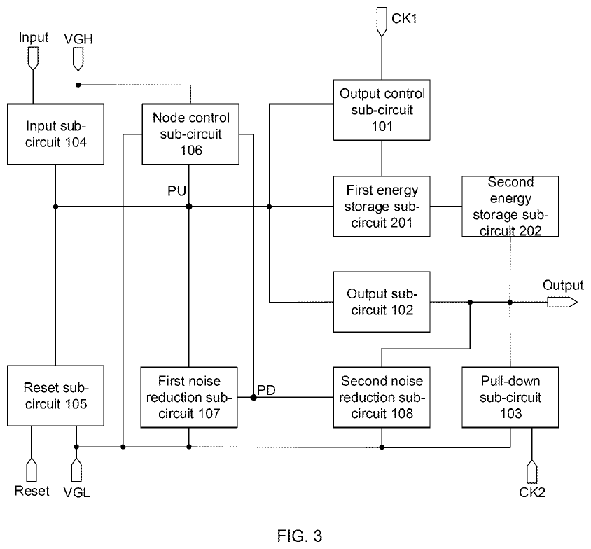

In some embodiments, as shown in FIGS. 3 to 5, the shift register further includes a pull-down sub-circuit 103.

The pull-down sub-circuit 103 is coupled to a second clock signal terminal CK2, the signal output terminal Output and a first voltage terminal VGL. The pull-down sub-circuit 103 is configured to transmit a first voltage signal vgl received at the first voltage terminal VGL to the signal output terminal Output in response to a second clock signal ck2 received at the second clock signal terminal CK2. For example, the first voltage signal vgl is a low level signal.

In the shift register, in a period when the voltage of the pull-up node PU is not boosted, the first voltage signal vgl is transmitted to the signal output terminal Output through the pull-down sub-circuit 103, which ensures that the shift register does not output the scanning signal in the period.

For example, as shown in FIGS. 4 and 5, the pull-down sub-circuit 103 includes a third transistor T3. A control electrode of the third transistor T3 is coupled to the second clock signal terminal CK2, a first electrode of the third transistor T3 is coupled to the first voltage terminal VGL, and a second electrode of the third transistor T3 is coupled to the signal output terminal Output. The third transistor T3 is configured to be turned on under control of the second clock signal ck2 to transmit the first voltage signal vgl to the signal output terminal Output.

In some embodiments, as shown in FIGS. 3 to 5, the shift register further includes a second energy storage sub-circuit 202. The second energy storage sub-circuit 202 is coupled between the first energy storage sub-circuit 201 and the signal output terminal Output, and is configured to keep the voltage of the pull-up node PU stable in a process of transmitting the boosted voltage of the pull-up node PU to the signal output terminal Output.

It will be understood that, in the process of transmitting the boosted voltage of the pull-up node PU to the signal output terminal Output, the voltage of the pull-up node PU slowly decreases due to an electric leakage. However, the scanning signal transmitted by the signal output terminal Output is capable of boosting a voltage of a terminal of the first energy storage sub-circuit 201 that is coupled to the second energy storage sub-circuit 202 through a terminal of the second energy storage sub-circuit 202 that is coupled to the signal output terminal. Therefore, the voltage of the pull-up node PU is further increased through the first energy storage sub-circuit 201, so that an reduction of the voltage of the pull-up node PU caused by the electric leakage and the further increase of the voltage of the pull-up node PU may reach a balance. As a result, the voltage of the pull-up node PU remains stable, and the scanning signal transmitted by the signal output terminal Output is more stable.

For example, as shown in FIGS. 4 and 5, the second energy storage sub-circuit includes a second capacitor C2, and a first terminal of the second capacitor C2 is coupled to the signal output terminal Output. In a case where the first energy storage sub-circuit 201 includes the first capacitor C1, a second terminal of the second capacitor C2 is coupled to the second terminal of the first capacitor C1.

In addition, a person of ordinary skill in the art will understand that, in addition to the above sub-circuits, the shift register usually further includes other sub-circuits such as an input sub-circuit, a plurality of control sub-circuits, a reset sub-circuit and a noise reduction sub-circuit. The present disclosure does not specifically limit specific arrangements of other sub-circuits, and the arrangements may be selected according to actual needs under the premise that the shift register is in normal operation.

In some embodiments, in a case where the shift register includes all the foregoing sub-circuits or part of the sub-circuits, as shown in FIGS. 3 to 5, the shift register further includes an input sub-circuit 104 and a reset sub-circuit 105.

The input sub-circuit 104 is coupled to a signal input terminal Input, a second voltage terminal VGH and the pull-up node PU. The input sub-circuit 104 is configured to transmit a second voltage signal vgh received at the second voltage terminal VGH to the pull-up node PU in response to an input signal input received at the signal input terminal Input.

The reset sub-circuit 105 is coupled to a reset signal terminal Reset, the first voltage terminal VGL and the pull-up node PU. The reset sub-circuit 105 is configured to output the first voltage signal vgl received at the first voltage terminal VGL to the pull-up node PU in response to the reset signal reset received at the reset signal terminal Reset.

For example, as shown in FIG. 4 or 5, the input sub-circuit 104 includes a fourth transistor T4. A control electrode of the fourth transistor T4 is coupled to the signal input terminal Input, a first electrode of the fourth transistor T4 is coupled to the second voltage terminal VGH, and a second electrode of the fourth transistor T4 is coupled to the pull-up node PU. The fourth transistor T4 is configured to transmit the second voltage signal vgh to the pull-up node PU under the control of the input signal input.

The reset sub-circuit 105 includes a fifth transistor T5. A control electrode of the fifth transistor T5 is coupled to the reset signal terminal Reset, a first electrode of the fifth transistor T5 is coupled to the first voltage terminal VGL, and a second electrode of the fifth transistor T5 is coupled to the pull-up node PU. The fifth transistor T5 is configured to transmit the first voltage signal vgl to the pull-up node PU under control of the reset signal reset.

In some embodiments, as shown in FIGS. 3 to 5, the shift register further includes the pull-down node PD, a node control sub-circuit 106, a first noise reduction sub-circuit 107 and a second noise reduction sub-circuit 108.

In some examples, the node control sub-circuit 106 is coupled to the second voltage terminal VGH, the pull-up node PU, the first voltage terminal VGL and the pull-down node PD. The node control sub-circuit 106 is configured to: transmit the first voltage signal vgl received at the first voltage terminal VGL to the pull-down node PD in response to the voltage of the pull-up node PU and the second voltage signal vgh received at the second voltage terminal VGH; and transmit the second voltage signal vgh received at the second voltage terminal VGH to the pull-down node PD in response to the voltage of the pull-up node PU and the second voltage signal vgh received at the second voltage terminal VGH.

For example, as shown in FIG. 4 or 5, the first control sub-circuit 106 includes a sixth transistor T6 and a seventh transistor T7.

A control electrode of the sixth transistor T6 is coupled to the second voltage terminal VGH, a first electrode of the sixth transistor T6 is coupled to the second voltage terminal VGH, and a second electrode of the sixth transistor T6 is coupled to the pull-down node PD. The sixth transistor T6 is configured to be turned on under the control of the second voltage signal vgh to transmit the second voltage signal vgh to the pull-down node PD.

A control electrode of the seventh transistor T7 is coupled to the pull-up node PU, a first electrode of the seventh transistor T7 is coupled to the first voltage terminal VGL, and a second electrode of the seventh transistor T7 is coupled to the pull-down node PD. The seventh transistor T7 is configured to be turned on under the control of the voltage of the pull-up node PU to transmit the first voltage signal vgl to the pull-down node PD.

In a case where the first control sub-circuit 106 includes the sixth transistor T6 and the seventh transistor T7, the first control sub-circuit achieves its function through a process that the sixth transistor T6 is turned on under the control of the second voltage signal vgh and the seventh transistor T7 is turned on under the control of the voltage of the pull-up node PU, so that the seventh transistor T7 transmits the first voltage signal vgl received at the first voltage terminal VGL to the pull-down node PD; and the sixth transistor T6 is turned on under the control of the second voltage signal vgh and the seventh transistor T7 is turned off under the control of the voltage of the pull-up node PU, so that the sixth transistor T6 transmits the second voltage signal vgh received at the second voltage terminal VGH to the pull-down node PD.

In embodiments of the present disclosure, the “size of the transistor” indicates a width-to-length ratio of a channel of the transistor. A person of ordinary skill in the art will understand that, a transistor generally includes a gate, an active layer, a source and a drain. Herein, the “channel” refers to a flow path for carriers formed in the active layer between the source and drain of the transistor when the active layer of the transistor is in a working state. The “width-to-length ratio of the channel” refers to a ratio of the width of the channel to the length of the channel. The length of the channel refers to a size of the channel in a direction X pointing from the source to the drain (or pointing from the drain to the source), and the width of the channel refers to a size of the channel in a direction perpendicular to the direction X.

In an example where the first voltage terminal VGL is a low voltage terminal, the second voltage terminal VGH is a high voltage terminal, and the sixth transistor and the seventh transistor are both NMOS transistors, the sixth transistor and the seventh transistor are both turned on when the voltage of the pull-up node PU is at a high level. A potential at the pull-down node PD may be controlled by setting a size of the seventh transistor T7 to be greater than a size of the sixth transistor T6, i.e., by setting a width-to-length ratio of a channel of the seventh transistor T7 to be greater than a width-to-length ratio of a channel of the sixth transistor T6. The width-to-length ratio of the channel of the seventh transistor T7 is greater than the width-to-length ratio of the channel of the sixth transistor T6, which may be considered that a resistance of the sixth transistor T6 is greater than a resistance of the seventh transistor T7. Therefore, in a case where the sixth transistor T6 is turned on under the control of the second voltage signal vgh, and the seventh transistor T7 is configured to be turned on under the control of the voltage of the pull-up node PU, a voltage applied to the sixth transistor T6 is larger, so as to reduce the voltage of the pull-down node PD. That is, it is ensured that in a case where the sixth transistor T6 and the seventh transistor T7 are both turned on, the pull-down node PD is still remained at a low level, which may be regarded as that the first voltage signal vgl is transmitted to the pull-down node PD.

In some examples, the first noise reduction sub-circuit 107 is coupled to the pull-up node PU, the pull-down node PD and the first voltage terminal VGL. The first noise reduction sub-circuit 107 is configured to transmit the first voltage signal vgl received at the first voltage terminal VGL to the pull-up node PU under the control of the voltage of the pull-down node PD, so as to perform noise reduction on the pull-up node PU.

For example, as shown in FIG. 4 or 5, the first noise reduction sub-circuit 107 includes an eighth transistor T8. A control electrode of the eighth transistor T8 is connected to the pull-down node PD, a first electrode of the eighth transistor T8 is coupled to the first voltage terminal VGL, and a second electrode of the eighth transistor T8 is coupled to the pull-up node PU. The eighth transistor T8 is configured to be turned on under the control of the voltage of the pull-down node PD to transmit the first voltage signal vgl to the pull-up node PU.

In some examples, the second noise reduction sub-circuit 108 is connected to the first voltage terminal VGL, the pull-down node PD and the signal output terminal Output. The second noise reduction sub-circuit 108 is configured to transmit the first voltage signal vgl from the first voltage terminal VGL to the signal output terminal Output under the control of the voltage of the pull-down node PD.

For example, as shown in FIG. 4 or 5, the second noise reduction sub-circuit 108 includes a ninth transistor T9. A control electrode of the ninth transistor T9 is coupled to the pull-down node PD, a first electrode of the ninth transistor T9 is coupled to the first voltage terminal VGL, and a second electrode of the ninth transistor T9 is coupled to the signal output terminal Output. The ninth transistor T9 is configured to be turned on under the control of the voltage of the pull-down node PD to transmit the first voltage signal vgl to the signal output terminal Output.

On this basis, a circuit structure of the shift register provided in the embodiments of the present disclosure will be described generally and exemplarily.

As shown in FIG. 4 or 5, the shift register includes the pull-up node PU, the output control sub-circuit 101, the first energy storage sub-circuit 201, the output sub-circuit 102, the pull-down sub-circuit 103, the input sub-circuit 104, and the reset sub-circuit 105, the pull-down node PD, the node control sub-circuit 106, the first noise reduction sub-circuit 107 and the second noise reduction sub-circuit 108. The output control sub-circuit 101 includes the first transistor T1, the output sub-circuit 102 includes the second transistor T2, the pull-down sub-circuit 103 includes the third transistor T3, the input sub-circuit 104 includes the fourth transistor T4, the reset sub-circuit 105 includes the fifth transistor T5, the node control sub-circuit 106 includes the sixth transistor T6 and the seventh transistor T7, the first noise reduction sub-circuit 107 includes the eighth transistor T8, the second noise reduction sub-circuit 108 includes the ninth transistor T9, and the first energy storage sub-circuit 201 includes the first capacitor C1.

The control electrode of the first transistor T1 is coupled to the pull-up node PU, the first electrode of the first transistor T1 is coupled to the first clock signal terminal CK1, and the second electrode of the first transistor T1 is coupled to the second terminal of the first capacitor C1. The first transistor T1 is configured to be turned on under the control of the voltage of the pull-up node PU to transmit the first clock signal ck1 to the second terminal of the first capacitor C1.

The first terminal of the first capacitor C1 is coupled to the pull-up node PU, and is further coupled to the control electrode of the first transistor T1. The first capacitor C1 is configured to store the voltage of the pull-up node PU.

The control electrode of the second transistor T2 is coupled to the pull-up node PU, the first electrode of the second transistor T2 is coupled to the pull-up node PU, and the second electrode of the second transistor T2 is coupled to the signal output terminal Output. The second transistor T2 is configured to be turned on under the control of the voltage of the pull-up node PU to transmit the boosted voltage of the pull-up node PU to the signal output terminal Output.

The control electrode of the third transistor T3 is coupled to the second clock signal terminal CK2, the first electrode of the third transistor T3 is coupled to the first voltage terminal VGL, and the second electrode of the third transistor T3 is coupled to the signal output terminal Output. The third transistor T3 is configured to be turned on under the control of the second clock signal ck2 to transmit the first voltage signal vgl to the signal output terminal Output.

The control electrode of the fourth transistor T4 is coupled to the signal input terminal Input, the first electrode of the fourth transistor T4 is coupled to the second voltage terminal VGH, and the second electrode of the fourth transistor T4 is coupled to the pull-up node PU. The fourth transistor T4 is configured to be turned on under the control of the input signal input to transmit the second voltage signal vgh to the pull-up node PU.

The control electrode of the fifth transistor T5 is coupled to the reset signal terminal Reset, the first electrode of the fifth transistor T5 is coupled to the first voltage terminal VGL, and the second electrode of the fifth transistor T5 is coupled to the pull-up node PU. The fifth transistor T5 is configured to be turned on under the control of the reset signal reset to transmit the first voltage signal vgl to the pull-up node PU.

The control electrode of the sixth transistor T6 is coupled to the second voltage terminal VGH, the first electrode of the sixth transistor T6 is coupled to the second voltage terminal VGH, and the second electrode of the sixth transistor T6 is coupled to the pull-down node PD. The sixth transistor T6 is configured to be turned on under the control of the second voltage signal vgh to transmit the second voltage signal vgh to the pull-down node PD.

The control electrode of the seventh transistor T7 is coupled to the pull-up node PU, the first electrode of the seventh transistor T7 is coupled to the first voltage terminal VGL, and the second electrode of the seventh transistor T7 is coupled to the pull-down node PD. The seventh transistor T7 is configured to be turned on under the control of the pull-up node PU to transmit the first voltage signal vgl to the pull-down node PD.

The control electrode of the eighth transistor T8 is coupled to the pull-down node PD, the first electrode of the eighth transistor T8 is coupled to the first voltage terminal VGL, and the second electrode of the eighth transistor T8 is coupled to the pull-up node PU. The eighth transistor T8 is configured to be turned on under the control of the voltage of the pull-down node PD to transmit the first voltage signal vgl to the pull-up node PU.

The control electrode of the ninth transistor T9 is coupled to the pull-down node PD, the first electrode of the ninth transistor T9 is coupled to the first voltage terminal VGL, and the second electrode of the ninth transistor T9 is coupled to the signal output terminal Output. The ninth transistor T9 is configured to be turned on under the control of the voltage of the pull-down node PD to transmit the first voltage signal vgl to the signal output terminal Output.

It will be noted that the transistors used in the shift register provided in the embodiments of the present disclosure may be N-type transistors or P-type transistors. For example, the transistors in the shift register provided in the embodiments of the present disclosure are all N-type transistors. The transistors used in the shift register provided in the embodiments of the present disclosure may be enhancement transistors, depletion transistors, or other switching devices with the same characteristic. The above transistors may also be amorphous silicon thin film transistors, polysilicon thin film transistors or amorphous-indium gallium zinc oxide thin film transistors, which is not limited.

In addition, the control electrode of the transistor used in the shift register is a gate of the transistor, the first electrode of the transistor may be a source and the second electrode of the transistor may be a drain, or the first electrode of the transistor may be a drain and the second electrode of the transistor may be a source, which is not limited. Since the source and the drain of the transistor may be symmetrical in structure, there may be no difference in structure between the source and the drain of the transistor. That is, there may be no difference in structure between the first electrode and the second electrode of the transistor in the embodiments of the present disclosure. For example, in a case where the transistor is the P-type transistor, the first electrode of the transistor is the source, and the second electrode of the transistor is the drain. For example, in a case where the transistor is the N-type transistor, the first electrode of the transistor is the drain, and the second electrode of the transistor is the source.

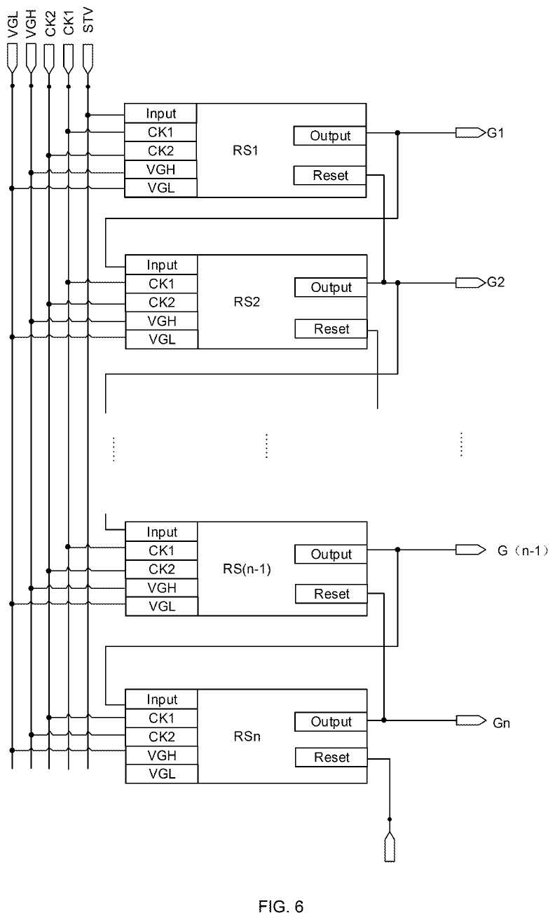

Some embodiments of the present disclosure further provide a gate driver circuit. As shown in FIG. 6, the gate driver circuit includes at least two cascaded shift registers RS described above. For example, the gate driver circuit includes n cascaded shift registers RS described above, which are RS1 to RSn.

Specifically, in the gate driver circuit, a signal input terminal Input of a first stage shift register RS1 is coupled to a start signal terminal STV.

A signal input terminal Input of any stage shift register RS other than the first stage shift register RS1 is coupled to a signal output terminal Output of a previous stage shift register RS of the present stage shift register RS. For example, a signal input terminal Input of a second stage shift register RS2 is coupled to a signal output terminal Output of the first stage shift register RS1. A signal input terminal Input of a third stage shift register RS3 is coupled to a signal output terminal Output of the second stage shift register RS2.

A reset signal terminal Reset of any stage shift register RS other than the last stage shift register RSn is coupled to a signal output terminal Output of a next stage shift register RS of the present stage shift register RS. For example, a reset signal terminal of the second stage shift register RS2 is coupled to a signal output terminal Output of the third stage shift register RS3. A reset signal terminal Reset of the third stage shift register RS3 is coupled to a signal output terminal Output of a fourth stage shift register RS4.

A reset signal terminal Reset of the last stage shift register RSn is coupled to a separately provided signal terminal for outputting a reset signal, or is coupled to the start signal terminal. (FIG. 6 is a schematic diagram only taking an example in which the reset signal terminal Reset of the last stage shift register RSn is coupled to the separately provided signal terminal for outputting the reset signal).

It will be understood herein that each stage shift register RS is coupled to a gate line G in a display panel. For example, as shown in FIG. 6, the display panel includes n gate lines (n is a positive integer, for example, n is 2000). In this case, the gate driver circuit further includes n-stage shift registers. In general, an i-th stage shift register RSi is coupled to an i-th gate line Gi in the display panel, and i is a positive integer that is greater than or equal to 1 and is less than or equal to n.

The gate driver circuit includes the shift register as described above, and has the same structure and beneficial effects as the shift register provided in the above embodiments. Since the structure and the beneficial effects of the shift register have been described in detail in the above embodiments, details will not be described herein again.

Some embodiments of the present disclosure further provide a display device. The display device includes the gate driver circuit provided in some embodiments of the present disclosure, and the display device also includes the shift register. The display device has the same structure and the beneficial effects as the shift register provided in the above embodiments. Since the structure and the beneficial effects of the shift register have been described in detail in the above embodiments, details will not be described herein again.

In some examples, the display device provided in the embodiments of the present disclosure is a liquid crystal display device, and the liquid crystal display device includes a liquid crystal display panel; or, the display device provided in the embodiments of the present disclosure is an organic light-emitting diode display device, and the organic light-emitting diode display device includes an organic light-emitting diode display panel. The display device in the embodiments of the present disclosure may be any product or component having a display function, such as a liquid crystal panel, an electronic paper, an OLED panel, a mobile phone, a tablet computer, a television, a display, a notebook computer, a digital picture frame or a navigator, which is not limited herein.

As for the liquid crystal display device, the gate driver circuit may boost a voltage of the scanning signal, thereby improving the charging efficiency. When a liquid crystal display panel is actually manufactured, a size of a thin film transistor in a sub-pixel (W/L, i.e., a width-to-length ratio of a channel) may be correspondingly reduced, thereby increasing an aperture ratio of the sub-pixel.

Some embodiments of the present disclosure further provide a driving method for a shift register. The driving method is applied to the shift register provided in some embodiments of the present disclosure.

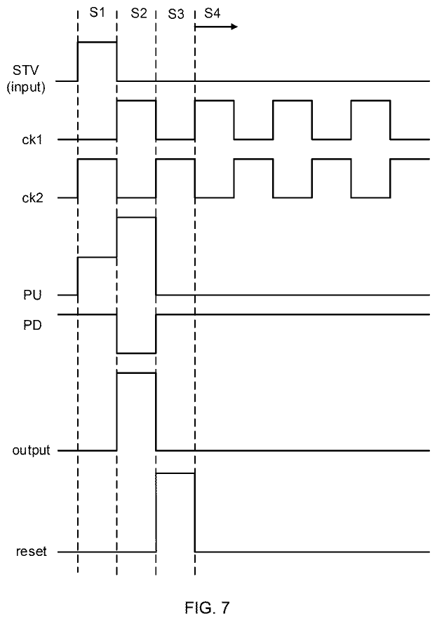

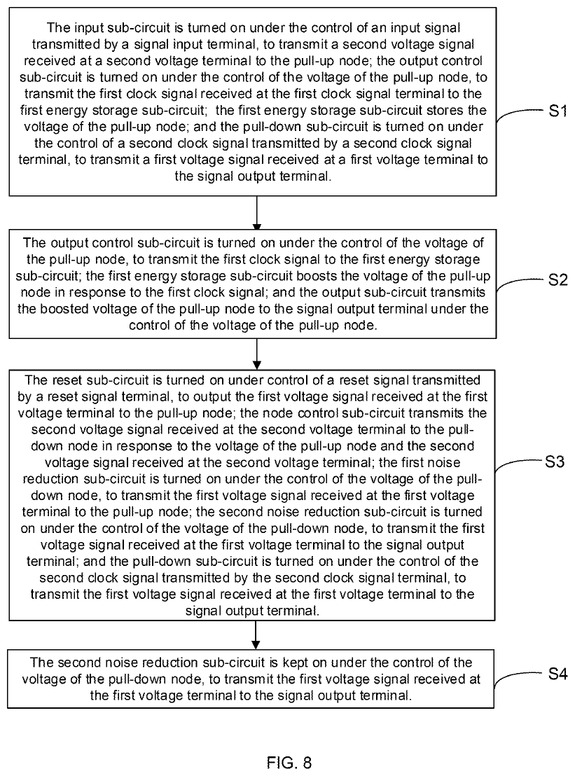

In a case where the shift register includes the pull-up node PU, the output control sub-circuit 101, the output sub-circuit 102 and the first energy storage sub-circuit 201, as shown in FIGS. 7 and 8, a frame cycle includes a charging period S1 and an outputting period S2.

The charging period S1 includes:

the output control sub-circuit 101 being turned on under the control of the voltage of the pull-up node PU, to transmit the first clock signal ck1 received at the first clock signal terminal CK1 to the first energy storage sub-circuit 201, and the first clock signal ck1 being at a low level; and

the voltage of the pull-up node PU being stored by the first energy storage sub-circuit 201.

For example, as shown in FIG. 4, in a case where the output control sub-circuit 101 includes the first transistor T1, and the first energy storage sub-circuit 201 includes the first capacitor C1,

in the charging period S1, the first transistor T1 is turned on under the control of the voltage of the pull-up node PU, to transmit the first clock signal ck1 received at the first clock signal terminal CK1 to the second terminal of the first capacitor C1. In this case, a potential at the second terminal of the first capacitor C1 is a low level potential of the first clock signal ck1, such as 0V. The first capacitor C1 stores the voltage of the pull-up node PU. In this case, a potential at the first terminal of the first capacitor C1 is the voltage of the pull-up node PU, such as 22V.

The outputting period S2 includes:

the output control sub-circuit 101 being turned on under the control of the voltage of the pull-down node PU, to transmit the first clock signal ck1 received at the first clock signal terminal CK1 to the first energy storage sub-circuit 201, and the first clock signal ck1 being at a high level;

the first energy storage sub-circuit 201 boosting the voltage of the pull-up node PU in response to the first clock signal ck1; and

the output sub-circuit 102 transmitting the boosted voltage of the pull-up node PU to the signal output terminal Output under the control of the voltage of the pull-up node PU.

For example, as shown in FIG. 2, in a case where the output control sub-circuit 101 includes the first transistor T1, the first energy storage sub-circuit 201 includes the first capacitor C1, and the output sub-circuit 102 includes the second transistor T2,

in the outputting period S2, the first transistor T1 is turned on under the control of the voltage of the pull-up node PU to transmit the first clock signal ck1 received at the first clock signal terminal CK1 to the second terminal of the first capacitor C1. In this case, a potential at the second terminal of the first capacitor C1 is the high level potential of the first clock signal ck1, such as 22V. Since the potential at the second terminal of the first capacitor C1 is boosted, the potential at the first terminal of the first capacitor C1 is also boosted accordingly, according to a bootstrap effect of the capacitor. In theory, the potential at the first terminal of the first capacitor C1 may rise from 22V to 44V, thereby boosting the voltage of the pull-up node PU. It will be noted that, in an actual circuit structure, for example, the voltage of the pull-up node PU is boosted to 30V, and the second transistor T2 is turned on under the control of the voltage of the pull-up node PU, to transmit the boosted voltage of the pull-up node PU (30V) to the signal output terminal Output.

It will be noted that the signal output terminal Output only outputs the scanning signal in the outputting period S2, and does not output the scanning signal in the charging period.

In some embodiments, the threshold voltage of the second transistor T2 included in the output sub-circuit 102 is great. As a result, in the charging period S1, the voltage of the pull-up node PU may not be able to turn on the second transistor T2, and may not be able to transmit the voltage of the pull-up node PU to the signal output terminal.

In some other embodiments, in a case where the shift register further includes the pull-down sub-circuit 103, the charging period S1 further includes: the pull-down sub-circuit 103 being turned on under the control of the second clock signal ck2 transmitted by the second clock signal terminal CK2, to transmit the first voltage signal vgl received at the first voltage terminal VGL to the signal output terminal Output. In this way, it may also be ensured that the shift register does not output the scanning signal in the charging period S1.

By using the driving method for the shift register, in the outputting period S2, the output sub-circuit 102 transmits the boosted voltage of the pull-up node PU to the signal output terminal Output. That is, the boosted voltage of the pull-up node PU is used as the scanning signal. In this way, the voltage of the scanning signal is increased without increasing the high level of the clock signal clk and the power consumption of the display device. Thus, the charging rate of the sub-pixel is increased, which is more conducive to the application of the gate driver circuit to the display devices with high-resolution and large-size.

In some embodiments, in a case where the shift register further includes the second energy storage sub-circuit 202, the outputting period S2 further includes:

the second energy storage sub-circuit 202 keeping the voltage of the pull-up node PU stable during a process of transmitting the boosted voltage of the pull-up node PU to the signal output terminal Output.

For example, in the outputting period S2, the signal output terminal Output outputs the boosted voltage of the pull-up node PU, so as to boost the voltage of the terminal of the second capacitor C2 coupled to the signal output terminal Output (i.e., the first terminal of the second capacitor C2). Under bootstrap actions of the second capacitor C2 and the first capacitor C1, the voltage of the pull-up node PU is further boosted, so that an reduction of the voltage of the pull-up node PU caused by the electric leakage and an further increase of the voltage of the pull-up node PU may reach a balance. As a result, the voltage of the pull-up node PU remains stable, and the scanning signal output by the signal output terminal Output is more stable.

In some embodiments, as shown in FIGS. 4, 5, 7 and 8, in a case where the shift register further includes the pull-down sub-circuit 103, the pull-down node PD, the input sub-circuit 104, the reset sub-circuit 105, the node control sub-circuit 106, the first noise reduction sub-circuit 107 and the second noise reduction sub-circuit 108, an entire process of the driving method for the shift register includes a charging period S1, an outputting period S2, a resetting period S3 and a noise reduction period S4.

The charging period S1 includes the following steps.

The input sub-circuit 104 is turned on under the control of the input signal input transmitted by the signal input terminal Input, to transmit the second voltage signal vgh received at the second voltage terminal VGH to the pull-up node PU.

In some examples, as for the first stage shift register, the input signal input from the signal input terminal Input is an STV signal (being short for Start Vertical, a start signal of the gate). As for a shift register other than the first stage shift register, the input signal input is an output signal output of a previous stage shift register.

The output control sub-circuit 101 is turned on under the control of the voltage of the pull-up node PU, to transmit the first clock signal ck1 received at the first clock signal terminal CK1 to the first energy storage sub-circuit 201, and the first clock signal ck1 is at a low level.

The first energy storage sub-circuit 201 stores the voltage of the pull-up node PU.

The pull-down sub-circuit 103 is turned on under the control of the second clock signal ck2 transmitted by the second clock signal terminal CK2, to transmit the first voltage signal vgl received at the first voltage terminal VGL to the signal output terminal Output.

The node control sub-circuit 106 transmits the first voltage signal vgl received at the first voltage terminal VGL to the pull-down node PD in response to the voltage of the pull-up node PU and the second voltage signal vgh received at the second voltage terminal VGH, which makes the voltage of the pull-down node PD a low level.

The first noise reduction sub-circuit 107 and the second noise reduction sub-circuit 108 are turned off under the control of the voltage of the pull-down node PD, and the reset sub-circuit 105 is turned off under the control of the reset signal reset.

For example, as shown in FIG. 4 or 5, in a case where the output control sub-circuit 101 includes the first transistor T1, the output sub-circuit 102 includes the second transistor T2, the pull-down sub-circuit 103 includes the third transistor T3, the input sub-circuit 104 includes the fourth transistor T4, the reset sub-circuit 105 includes the fifth transistor T5, the node control sub-circuit 106 includes the sixth transistor T6 and the seventh transistor T7, the first noise reduction sub-circuit 107 includes the eighth transistor T8, the second noise reduction sub-circuit 108 includes the ninth transistor T9, and the first energy storage sub-circuit 201 includes the first capacitor C1, the charging period includes the following steps.

The fourth transistor T4 is turned on under the control of the input signal input, to transmit the second voltage signal vgh received at the second voltage terminal VGH to the pull-up node PU and the first terminal of the first capacitor C1. The first transistor T1 is turned on under the control of the voltage of the pull-up node PU, to transmit the first clock signal ck1 to the second terminal of the first capacitor C1. The first clock signal ck1 is at a low level in the meantime.

The seventh transistor T7 is turned on under the control of the high level of the pull-up node PU, to transmit a first voltage signal vg received at the first voltage terminal VGL to the pull-down node PD. It will be noted that, since a size of the seventh transistor T7 is greater than a size of the sixth transistor T6, even if the sixth transistor T6 is in a turn-on state under the control of the second voltage signal vgh, the first voltage signal vgl (a low level) of the first voltage terminal VGL may still ensure that the pull-down node PD remains at a low potential.

In some examples, the second transistor T2 is turned on under the control of the voltage of the pull-up node PU. In the meantime, the third transistor T3 is turned on under the control of the high level of the second clock signal terminal CK2, to transmit the first voltage signal vgl received at the first voltage terminal VGL to the signal output terminal Output. In a case where a size of the third transistor T3 is greater than a size of the second transistor T2, the first voltage signal vgl (the low level) of the first voltage terminal VGL may still ensure that the signal output terminal Output remains at a low level, thereby ensuring that the signal output terminal Output outputs the first voltage signal vgl (the low level) in the charging period S1.

In some other examples, a threshold voltage of the second transistor T2 is relatively great. In the charging period S1, the voltage of the pull-up node PU may not be able to turn on the second transistor T2, that is, the second transistor T2 is in a turn-off state. The third transistor T3 is turned on under the control of the high level of the second clock signal terminal CK2, to transmit the first voltage signal vgl received at the first voltage terminal VGL to the signal output terminal Output.

The fifth transistor T5, the eighth transistor T8 and the ninth transistor T9 are all in a turn-off state in the charging period S1.

The outputting period S2 includes the following steps.

The output control sub-circuit 101 is turned on under the control of the voltage of the pull-up node PU, to transmit the first clock signal ck1 received at the first clock signal terminal CK1 to the first energy storage sub-circuit 201. Since the first energy storage sub-circuit 201 stores the voltage of the pull-up node PU in the charging period S1, the first energy storage sub-circuit 201 discharges electricity to the pull-up node PU in the outputting period S2, so that the voltage of the pull-up node PU remains a high voltage, which may enable the output control sub-circuit 101 to remain in a turn-on state. In this period, the first clock signal ck1 is at a high level.

The first energy storage sub-circuit 201 boosts the voltage of the pull-up node PU in response to the first clock signal ck1.

The output sub-circuit 102 is turned on under the control of the voltage of the pull-up node PU, to transmit the boosted voltage of the pull-up node PU to the signal output terminal Output.

The node control sub-circuit 106 transmits the first voltage signal vgl received at the first voltage terminal VGL to the pull-down node PD in response to the voltage of the pull-up node PU and the second voltage signal vgh received at the second voltage terminal VGH. In the meantime, the voltage of the pull-down node PD is at a low level.

In the outputting period S2, the pull-down sub-circuit 103 is turned off under the control of the second clock signal ck2 (which is at a low level in this period); the input sub-circuit 104 is turned off under the control of the input signal input; the first noise reduction sub-circuit 107 and the second noise reduction sub-circuit 108 are turned off under the control of the voltage of the pull-down node PD, and the reset sub-circuit 105 is turned off under the control of the reset signal reset.

For example, as shown in FIG. 4 or 5, in a case where the output control sub-circuit 101 includes the first transistor T1, the output sub-circuit 102 includes the second transistor T2, the pull-down sub-circuit 103 includes the third transistor T3, the input sub-circuit 104 includes the fourth transistor T4, the reset sub-circuit 105 includes the fifth transistor T5, the node control sub-circuit 106 includes the sixth transistor T6 and the seventh transistor T7, the first noise reduction sub-circuit 107 includes the eighth transistor T8, the second noise reduction sub-circuit 108 includes the ninth transistor T9, and the first energy storage sub-circuit 201 includes the first capacitor C1, the outputting period includes:

the first capacitor C1 discharging the voltage stored in the charging period S1 to the pull-up node PU, and the third transistor T3 being turned on under the control of the voltage of the pull-up node PU to transmit the first clock signal (being a high level signal) received at the first clock signal terminal CK1 to the second terminal of the first capacitor C1, and the potential at the first terminal of the first capacitor C1 being boosted under the bootstrap action of the first capacitor C1, thereby boosting the voltage of the pull-up node PU. In this case, the second transistor T2 is turned on under the control of the boosted voltage of the pull-up node PU, to transmit the boosted voltage of the pull-up node PU (serving as the scanning signal) to the signal output terminal Output.

In addition, in the outputting period S2, the sixth transistor T6 and the seventh transistor T7 remain in a turn-on state (which is the same as the charging period S1), which makes the pull-down node PD remain at the low potential. The third transistor T3, the fourth transistor T4, the fifth transistor T5, the eighth transistor T8 and the ninth transistor T9 are all in a turn-off state.

It will be noted here that, for boosting the potential of the pull-up node PU under the bootstrap action of the first capacitor C1, in a case where the level of the second voltage signal vgh is equal to the high level of the first clock signal ck1, for example, both of them are 22V, the potential at the pull-up node PU may be theoretically boosted to twice the high level of the first clock signal terminal CK1, In actual simulation, it is not absolutely possible to reach twice the high level of the first clock signal terminal CK1, For example, in a case where the high level of the first clock signal terminal CK1 is 22V, the voltage of the pull-up node PU is boosted to 30V under the bootstrap action of the first capacitor C1, It will be seen that, the shift register may boost the voltage of the pull-up node PU, thereby increasing the voltage of the scanning signal output by the signal output terminal Output.

As shown in FIG. 7, the driving method further includes a resetting period S3 after the outputting period S2. The resetting period S3 includes the following steps.

The reset sub-circuit 105 is turned on under the control of the reset signal reset transmitted by the reset signal terminal Reset, to transmit the first voltage signal vgl received at the first voltage terminal VGL to the pull-up node PU. In the meantime, the voltage of the pull-up node PU is at a low level, and the output sub-circuit 102 is turned off under the control of the voltage of the pull-up node PU, so as to stop transmitting the voltage of the pull-up node PU to the signal output terminal Output.

The node control sub-circuit 106 transmits the second voltage signal vgh received at the second voltage terminal VGH to the pull-down node PD in response to the voltage of the pull-up node PU and the second voltage signal vgh received at the second voltage terminal VGH. In the meantime, the voltage of the pull-down node PD is a high voltage.

The first noise reduction sub-circuit 107 is turned on under the control of the voltage of the pull-down node PD, to transmit the first voltage signal vgl received at the first voltage terminal VGL to the pull-up node PU.

The second noise reduction sub-circuit 108 is turned on under the control of the voltage of the pull-down node PD, to transmit the first voltage signal vgl received at the first voltage terminal VGL to the signal output terminal Output.

The pull-down sub-circuit 103 is turned on under the control of the second clock signal ck2 transmitted by the second clock signal terminal CK2, to transmit the first voltage signal vgl received at the first voltage terminal VGL to the signal output terminal Output.

The output control sub-circuit 101 and the output sub-circuit 102 are turned off under the control of the voltage of the pull-up node PU.

For example, as shown in FIG. 4 or 5, in a case where the output control sub-circuit 101 includes the first transistor T1, the output sub-circuit 102 includes the second transistor T2, the pull-down sub-circuit 103 includes the third transistor T3, the input sub-circuit 104 includes the fourth transistor T4, the reset sub-circuit 105 includes the fifth transistor T5, the node control sub-circuit 106 includes the sixth transistor T6 and the seventh transistor T7, the first noise reduction sub-circuit 107 includes the eighth transistor T8, the second noise reduction sub-circuit 108 includes the ninth transistor T9, and the first energy storage sub-circuit 201 includes the first capacitor C1, the resetting period S3 includes:

the fifth transistor T5 being turned on under the control of the high level reset signal reset transmitted by the reset signal terminal Reset, to transmit the first voltage signal vg received at the first voltage terminal VGL to the pull-up node PU, which reduces the voltage of the pull-up node PU and achieves reset; the seventh transistor T7 being turned off under the control of the voltage of the pull-up node PU, and the sixth transistor T6 being turned on under the control of the second voltage signal vgh transmitted by the second voltage terminal VGH, to transmit the second voltage signal vgh to the pull-down node PD and increase the voltage of the pull-down node PD; and the eighth transistor T8 being turned on under the control of the voltage of the pull-down node PD, to transmit the first voltage signal vgl received at the first voltage terminal VGL to the pull-up node PU for reset; and in the meantime, the ninth transistor T9 being turned on under the control of the voltage of the pull-down node PD, to transmit the first voltage signal vgl received at the first voltage terminal VGL to the signal output terminal Output for reset.

In addition, in the resetting period S3, the third transistor T3 is turned on under the control of the second clock signal ck2 (which is at the high level in this period) transmitted by the second clock signal terminal CK2, to transmit the first voltage signal vgl received at the first voltage terminal VGL to the signal output terminal Output.

The first transistor T1, the second transistor T2 and the fourth transistor T4 are all in a turn-off state in the resetting period S3.

In a period after the resetting period S3 and before a next frame, the shift register enters the noise reduction period S4. The noise reduction period S4 includes the following steps.

The second noise reduction sub-circuit 108 is turned on under the control of the voltage of the pull-down node PD, to transmit the first voltage signal vgl received at the first voltage terminal VGL to the signal output terminal Output, so as to perform a noise reduction on the signal output terminal Output continuously.

The pull-down sub-circuit 103 is periodically turned on and off under the control of the second clock signal ck2. In a case where the pull-down sub-circuit 103 is turned on, the first voltage signal vgl received at the first voltage terminal VGL may be transmitted to the signal output terminal Output, which may also implement the noise reduction.

In addition, the node control sub-circuit 106 transmits the second voltage signal vgh received at the second voltage terminal VGH to the pull-down node PD in response to the voltage of the pull-up node PU and the second voltage signal vgh received at the second voltage terminal VGH, so as to increase the potential at the pull-down node PD. The first noise reduction sub-circuit 107 is turned on under the control of the voltage of the pull-down node PD, to transmit the voltage of the first voltage terminal VGL to the pull-up node PU.

The output sub-circuit 102, the output control sub-circuit 101, and the input sub-circuit 104 are all in a turn-off state in the noise reduction period S4.

For example, as shown in FIG. 4 or 5, in a case where the output control sub-circuit 101 includes the first transistor T1, the output sub-circuit 102 includes the second transistor T2, the pull-down sub-circuit 103 includes the third transistor T3, the input sub-circuit 104 includes the fourth transistor T4, the reset sub-circuit 105 includes the fifth transistor T5, the node control sub-circuit 106 includes the sixth transistor T6 and the seventh transistor T7, the first noise reduction sub-circuit 107 includes the eighth transistor T8, the second noise reduction sub-circuit 108 includes the ninth transistor T9, and the first energy storage sub-circuit 201 includes the first capacitor C1, the noise reduction period S4 includes the following steps.

The ninth transistor T9 is turned on under the control of the voltage of the pull-down node PD, to transmit the first voltage signal vg received at the first voltage terminal VGL to the signal output terminal Output for noise reduction. The third transistor T3 is periodically turned on and off under the control of the second clock signal terminal CK2 (which has a high level and a low level). In a case where the third transistor T3 is turned on, the first voltage signal vgl received at the first voltage terminal VGL is transmitted to the signal output terminal Output for noise reduction.

In the noise reduction period S4, the sixth transistor T6 is turned on under the control of the second voltage signal vgh, and the seventh transistor T7 is turned off under the control of the pull-up node PU to transmit the second voltage signal vgh received at the second voltage terminal VGH to the pull-down node PD. The eighth transistor T8 is in a turn-on state under the control of the pull-down node PD. The first transistor T1, the second transistor T2, the fourth transistor T4, the fifth transistor T5, and the seventh transistor T7 are all in a turn-off state.

The turn-on and turn-off processes of the transistors in the above embodiments are described by taking an example in which all the transistors are N-type transistors, the first voltage terminal VGL is a low level voltage terminal, the second voltage terminal VGH is a high level voltage terminal, duty ratios of the first clock signal ck1 and the second clock signal ck2 are both fifty percent, and the first clock signal ck1 and the second clock signal ck2 have completely opposite high and low level changes. In a case where all the transistors are the P-type transistors, it is necessary to invert control signals, the first voltage terminal, and the second voltage terminal in FIG. 5.

Some embodiments of the present disclosure further provide another driving method for the above shift register. The driving method is based on a case where duty ratios of the first clock signal ck1 and the second clock signal ck2 are both less than fifty percent. That is, in a period of level change, a time proportion of the high level is less than a time proportion of the low level. The following takes the shift register shown in FIGS. 4 and 5 as an example, and the driving method is described by taking an example in which all the transistors included in the shift registers are N-type transistors, the first voltage terminal VGL is the low level voltage terminal, and the second voltage terminal VGH is the high level voltage terminal. A circuit structure included in the shift register may be referred to the above description, which is not described herein again.

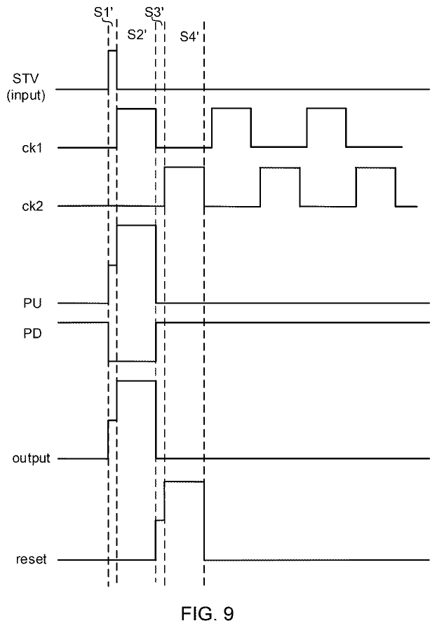

As shown in FIG. 9, the driving method includes: a charging period S1′, an outputting period S2′, a first resetting period S3, and a second resetting period S4′.

The charging period S1′ includes the following steps.

The level of the input signal input transmitted by the input signal terminal Input is a high level. The fourth transistor T4 is turned on under the control of the input signal input, to transmit the second voltage signal vgh received at the second voltage terminal VGH to the pull-up node PU, so that the voltage of the pull-up node PU is the voltage of the second voltage signal vgh, such as 22V.

The first transistor is turned on under the control of the voltage of the pull-up node PU, to transmit the first clock signal ck1 received at the first clock signal terminal CK1 (in this case, the level of the first clock signal ck1 is a low level, such as 0V) to the second terminal of the first capacitor C1. In the meantime, the first capacitor C1 stores the voltage of the pull-up node PU, and the voltage of the first terminal of the first capacitor C1 is the voltage of the pull-up node PU.

In some examples, the second transistor T2 is turned on under the control of the voltage of the pull-up node PU, to transmit the voltage of the pull-up node PU to the signal output terminal Output. Since the gate driver circuit turns on several rows of gate lines in advance, even if the second transistor T2 is turned on, the pixel driver circuit included in the sub-pixel will not receive data signals, and the sub-pixel will not be charged. Therefore, in the charging period S1′, the voltage transmitted to the signal output terminal Output has no effect on sub-pixel charging.

The level of the second clock signal ck2 of the second clock signal terminal CK2 is a low level, and the third transistor T3 is turned off under the control of the second clock signal ck2. The level of the reset signal reset of the reset signal terminal Reset is a low level, and the fifth transistor T5 is turned off under the control of the reset signal reset.

The sixth transistor is turned on under the control of the second voltage signal vgh, the seventh transistor T7 is turned on under the control of the voltage of the pull-up node PU, and the seventh transistor T7 transmits the first voltage signal vgl received at the first voltage terminal VGL to the pull-down node PD. Since the size of the seventh transistor T7 is greater than the size of the sixth transistor, the potential at the pull-down node PD is a low potential (the principle herein may refer to the above description).

The eighth transistor T8 and the ninth transistor T9 are turned off under the control of the voltage of the pull-down node PD.

The outputting period S2′ includes the following steps.

The voltage of the pull-up node PU remains at a high level (for example, 22V) under the action of the first capacitor C1, The first transistor T1 is turned on under the control of the voltage of the pull-up node PU, to transmit the first clock signal ck1 received at the first clock signal terminal CK1 (in this case, the level of the first clock signal ck1 is a high level, such as 22V) to the second terminal of the first capacitor C1. The voltage of the first terminal of the first capacitor C1 is boosted under the bootstrap action of the first capacitor C1, thereby boosting the voltage of the pull-up node PU. For example, the voltage of the pull-up node PU may be boosted to 44V in theory.

The second transistor T2 is turned on under the control of the voltage of the pull-up node PU, to transmit the boosted voltage of the pull-up node PU to the signal output terminal Output, and the boosted voltage of the pull-up node PU is output as the scanning signal.

In this case, referring to FIG. 5, the first terminal of the second capacitor C2 is coupled to the signal output terminal Output. In a process that the second transistor T2 transmits the boosted voltage of the pull-up node PU to the signal output terminal Output, the voltage of the pull-up node PU may be further boosted under the bootstrap actions of the second capacitor C2 and the first capacitor C1, so that an reduction of the voltage of the pull-up node PU caused by electric leakage and an further increase of the voltage of the pull-up node PU may reach a balance. As a result, the voltage of the pull-up node PU remains stable.

The level of the second clock signal ck2 of the second clock signal terminal CK2 is a low level, and the third transistor T3 is turned off under the control of the second clock signal ck2. The level of the reset signal reset transmitted by the reset signal terminal Reset is a low level, and the fifth transistor T5 is turned off under the control of the reset signal reset.

The sixth transistor is turned on under the control of the second voltage signal vgh, the seventh transistor T7 is turned on under the control of the voltage of the pull-up node PU, and the seventh transistor T7 transmits the first voltage signal vgl received at the first voltage terminal VGL to the pull-down node PD, so that the potential at the pull-down node PD remains low.

The eighth transistor T8 and the ninth transistor T9 are turned off under the control of the voltage of the pull-down node PD.

The first resetting period S3′ includes the following steps.

The level of the first clock signal ck1 transmitted by the first clock signal terminal CK1 is a low level, and the voltage of the pull-up node PU remains high. The first transistor T1 is turned on under the control of the voltage of the pull-up node PU, to transmit the first clock signal ck1 to the second terminal of the first capacitor C1. The potential at the first terminal of the first capacitor C1 is pulled down under the bootstrap action of the capacitor, so that the voltage of the pull-up node PU is pulled down. In the meantime, the first transistor T1 transmits the first clock signal ck1 to the second terminal of the second capacitor C1. The potential at the first terminal of the second capacitor C2 is pulled down under the bootstrap action of the capacitor, so that the potential at the signal output terminal Output also decreases.

In addition, in this period, the level of the second clock signal ck2 transmitted by the second clock signal terminal CK2 remains the low level, and the third transistor T3 is turned off under the control of the second clock signal ck2. The level of the reset signal reset of the reset signal terminal Reset is boosted, however, the potential is not high enough to turn on the fifth transistor T5, and the fifth transistor T5 remains in a turn-off state under the control of the reset signal reset.

The sixth transistor is turned on under the control of the second voltage signal vgh, and the seventh transistor T7 is turned on under the control of the voltage of the pull-up node PU. The seventh transistor T7 transmits the first voltage signal vgl received at the first voltage terminal VGL to the pull-down node PD, so that the potential at the pull-down node PD remains low.

The eighth transistor T8 and the ninth transistor T9 are turned off under the control of the voltage of the pull-down node PD.

The second resetting period S4′ includes the following steps.

The level of the reset signal reset transmitted by the reset signal terminal Reset is further boosted. The fifth transistor T5 is turned on under the control of the reset signal reset, to transmit the first voltage signal vgl received at the first voltage terminal VGL to the pull-up node PU, and the voltage of the pull-up node PU is pulled down, so that under the control of the voltage of the pull-up node PU, the first transistor T1 is turned off, the second transistor T2 is turned off, and the seventh transistor T7 is turned off.

The sixth transistor is kept on under the control of the second voltage signal vgh, to transmit the second voltage signal vgh received at the second voltage terminal VGH to the pull-down node PD, which increases the potential at the pull-down node PD. The eighth transistor T8 is turned on under the control of the voltage of the pull-down node PD, to transmit the first voltage signal vgl received at the first voltage terminal VGL to the pull-up node PU. The ninth transistor T9 is turned on under the control of the voltage of the pull-down node PD, to transmit the first voltage signal vgl received at the first voltage terminal VGL to the signal output terminal Output.

The level of the second clock signal ck2 transmitted by the second clock signal terminal CK2 is a high level. The third transistor T3 is turned on under the control of the second clock signal ck2, to transmit the first voltage signal vgl received at the first voltage terminal VGL to the signal output terminal Output.

A person of ordinary skill in the art will understand that, all or part of the steps in the above method embodiments may be implemented by using hardware related to program instructions. The program instructions may be stored in a computer readable storage medium for performing the steps included in the method in the above embodiments. The storage medium includes various media capable of storing program codes, such as a read-only memory (ROM), a random-access memory (RAM), a magnetic disk, or an optical disk.

The forgoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

1. A shift register, comprising a pull-up node, an output control sub-circuit, a first energy storage sub-circuit and an output sub-circuit, wherein
the output control sub-circuit is coupled to the pull-up node, a first clock signal terminal and the first energy storage sub-circuit; and the output control sub-circuit is configured to transmit a first clock signal received at the first clock signal terminal to the first energy storage sub-circuit under control of a voltage of the pull-up node;
the first energy storage sub-circuit is coupled to the pull-up node and the output control sub-circuit; and the first energy storage sub-circuit is configured to store the voltage of the pull-up node, and boost the voltage of the pull-up node under action of the first clock signal; and
the output sub-circuit is coupled to the pull-up node and a signal output terminal; and the output sub-circuit is configured to transmit the boosted voltage of the pull-up node to the signal output terminal under the control of the voltage of the pull-up node.

2. The shift register according to claim 1, wherein
the output control sub-circuit includes a first transistor, a control electrode of the first transistor is coupled to the pull-up node, a first electrode of the first transistor is coupled to the first clock signal terminal, and a second electrode of the first transistor is coupled to the first energy storage sub-circuit;
the first energy storage sub-circuit includes a first capacitor, a first terminal of the first capacitor is coupled to the pull-up node, and a second terminal of the first capacitor is coupled to the second electrode of the first transistor; and
the output sub-circuit includes a second transistor, a control electrode of the second transistor is coupled to the pull-up node, a first electrode of the second transistor is coupled to the pull-up node, and a second electrode of the second transistor is coupled to the signal output terminal.

3. The shift register according to claim 1, further comprising a pull-down sub-circuit, wherein
the pull-down sub-circuit is coupled to a second clock signal terminal, the signal output terminal and a first voltage terminal, and is configured to transmit a first voltage signal received at the first voltage terminal to the signal output terminal in response to a second clock signal received at the second clock signal terminal.

4. The shift register according to claim 3, wherein the pull-down sub-circuit includes a third transistor, a control electrode of the third transistor is coupled to the second clock signal terminal, a first electrode of the third transistor is coupled to the first voltage terminal, and a second electrode of the third transistor is coupled to the signal output terminal.

5. The shift register according to claim 1, further comprising a second energy storage sub-circuit, wherein
the second energy storage sub-circuit is coupled between the first energy storage sub-circuit and the signal output terminal, and is configured to keep the voltage of the pull-up node stable in a process of transmitting the boosted voltage of the pull-up node to the signal output terminal.

6. The shift register according to claim 5, wherein the second energy storage sub-circuit includes a second capacitor, and a first terminal of the second capacitor is coupled to the signal output terminal; and in a case where the first energy storage sub-circuit includes a first capacitor, a second terminal of the second capacitor is coupled to the first energy storage sub-circuit.

7. The shift register according to claim 1, further comprising an input sub-circuit and a reset sub-circuit, wherein
the input sub-circuit is coupled to a signal input terminal, a second voltage terminal and the pull-up node, and is configured to transmit a second voltage signal received at the second voltage terminal to the pull-up node in response to an input signal received at the signal input terminal; and
the reset sub-circuit is coupled to a reset signal terminal, a first voltage terminal and the pull-up node, and is configured to transmit a first voltage signal received at the first voltage terminal to the pull-up node in response to a reset signal received at the reset signal terminal.

8. The shift register according to claim 7, wherein
the input sub-circuit includes a fourth transistor, a control electrode of the fourth transistor is coupled to the signal input terminal, a first electrode of the fourth transistor is coupled to the second voltage terminal, and a second electrode of the fourth transistor is coupled to the pull-up node; and
the reset sub-circuit includes a fifth transistor, a control electrode of the fifth transistor is coupled to the reset signal terminal, a first electrode of the fifth transistor is coupled to the first voltage terminal, and a second electrode of the fifth transistor is coupled to the pull-up node.

9. The shift register according to claim 1, further comprising a pull-down node, a node control sub-circuit, a first noise reduction sub-circuit and a second noise reduction sub-circuit, wherein
the node control sub-circuit is coupled to a second voltage terminal, the pull-up node, a first voltage terminal and the pull-down node;
the node control sub-circuit is configured to transmit a first voltage signal received at the first voltage terminal to the pull-down node in response to the voltage of the pull-up node and a second voltage signal received at the second voltage terminal; and to transmit the second voltage signal received at the second voltage terminal to the pull-down node in response to the voltage of the pull-up node and the second voltage signal received at the second voltage terminal;
the first noise reduction sub-circuit is coupled to the pull-up node, the pull-down node and the first voltage terminal, and is configured to transmit the first voltage signal received at the first voltage terminal to the pull-up node under control of a voltage of the pull-down node; and
the second noise reduction sub-circuit is coupled to the pull-down node, the first voltage terminal and the signal output terminal, and is configured to transmit the first voltage signal received at the first voltage terminal to the signal output terminal under the control of the voltage of the pull-down node.

10. The shift register according to claim 9, wherein
the node control sub-circuit includes a sixth transistor and a seventh transistor; a control electrode of the sixth transistor is coupled to the second voltage terminal, a first electrode of the sixth transistor is coupled to the second voltage terminal, and a second electrode of the sixth transistor is coupled to the pull-down node; a control electrode of the seventh transistor is coupled to the pull-up node, a first electrode of the seventh transistor is coupled to the first voltage terminal, and a second electrode of the seventh transistor is coupled to the pull-down node;
the first noise reduction sub-circuit includes an eighth transistor, a control electrode of the eighth transistor is coupled to the pull-down node, a first electrode of the eighth transistor is coupled to the first voltage terminal, and a second electrode of the eighth transistor is coupled to the pull-up node; and
the second noise reduction sub-circuit includes a ninth transistor, a control electrode of the ninth transistor is coupled to the pull-down node, a first electrode of the ninth transistor is coupled to the first voltage terminal, and a second electrode of the ninth transistor is coupled to the signal output terminal.

11. The shift register according to claim 10, wherein a size of the seventh transistor is greater than a size of the sixth transistor.

12. The shift register according to claim 1, further comprising a pull-down sub-circuit, an input sub-circuit, a reset sub-circuit, a pull-down node, a node control sub-circuit, a first noise reduction sub-circuit and a second noise reduction sub-circuit; wherein
the output control sub-circuit includes a first transistor, the first energy storage sub-circuit includes a first capacitor, the output sub-circuit includes a second transistor, the pull-down sub-circuit includes a third sub-circuit, the input sub-circuit includes a fourth transistor, the reset sub-circuit includes a fifth transistor, the node control sub-circuit includes a sixth transistor and a seventh transistor, the first noise reduction sub-circuit includes an eighth transistor, and the second noise reduction sub-circuit includes a ninth transistor;
a control electrode of the first transistor is coupled to the pull-up node, a first electrode of the first transistor is coupled to the first clock signal terminal, and a second terminal of the first transistor is coupled to a second terminal of the first capacitor;
a first terminal of the first capacitor is coupled to the pull-up node, and is further coupled to the control electrode of the first transistor;
a control electrode of the second transistor is coupled to the pull-up node, a first electrode of the second transistor is coupled to the pull-up node, and a second electrode of the second transistor is coupled to the signal output terminal;
a control electrode of the third transistor is coupled to a second clock signal terminal, a first electrode of the third transistor is coupled to a first voltage terminal, and a second electrode of the third transistor is coupled to the signal output terminal;
a control electrode of the fourth transistor is coupled to a signal input terminal, a first electrode of the fourth transistor is coupled to a second voltage terminal, and a second electrode of the fourth transistor is coupled to the pull-up node;
a control electrode of the fifth transistor is coupled to a reset signal terminal, a first electrode of the fifth transistor is coupled to the first voltage terminal, and a second electrode of the fifth transistor is coupled to the pull-up node;
a control electrode of the sixth transistor is coupled to the second voltage terminal, a first electrode of the sixth transistor is coupled to the second voltage terminal, and a second electrode of the sixth transistor is coupled to the pull-down node;
a control electrode of the seventh transistor is coupled to the pull-up node, a first electrode of the seventh transistor is coupled to the first voltage terminal, and a second electrode of the seventh transistor is coupled to the pull-down node;
a control electrode of the eighth transistor is coupled to the pull-down node, a first electrode of the eighth transistor is coupled to the first voltage terminal, and a second electrode of the eighth transistor is coupled to the pull-up node; and
a control electrode of the ninth transistor is coupled to the pull-down node, a first electrode of the ninth transistor is coupled to the first voltage terminal, and a second electrode of the ninth transistor is coupled to the signal output terminal.

13. A gate driver circuit, comprising at least two cascaded shift registers according to claim 1, wherein
a signal input terminal of a first stage shift register is coupled to a start signal terminal;
a signal input terminal of any stage shift register other than the first stage shift register is coupled to a signal output terminal of a previous stage shift register of the any stage shift register;
a reset signal terminal of any stage shift register other than a last stage shift register is coupled to a signal output terminal of a next stage shift register of this any stage shift register; and
a reset signal terminal of the last stage shift register is coupled to a separately provided signal terminal for outputting a reset signal, or is coupled to the start signal terminal.

14. A display device, comprising the gate driver circuit according to claim 13.

15. A driving method for a shift register, applied to the shift register according to claim 1, the driving method comprising a frame cycle including a charging period and an outputting period, wherein
the charging period includes:
the output control sub-circuit being turned on under the control of the voltage of the pull-up node, to transmit the first clock signal received at the first clock signal terminal to the first energy storage sub-circuit; and
storing, by the first energy storage sub-circuit, the voltage of the pull-up node; and
the outputting period includes:
the output control sub-circuit being turned on under the control of the voltage of the pull-up node, to transmit the first clock signal to the first energy storage sub-circuit;
boosting, by the first energy storage sub-circuit, the voltage of the pull-up node in response to the first clock signal; and
transmitting, by the output sub-circuit, the boosted voltage of the pull-up node to the signal output terminal under the control of the voltage of the pull-up node.

16. The driving method according to claim 15, wherein in a case where the shift register further includes a pull-down sub-circuit, the charging period further includes:
the pull-down sub-circuit being turned on under the control of a second clock signal transmitted by a second clock signal terminal, to transmit a first voltage signal received at a first voltage terminal to the signal output terminal.

17. The driving method according to claim 15, wherein in a case where the shift register further includes a second energy storage sub-circuit, the outputting period further includes:
keeping, by the second energy storage sub-circuit, the voltage of the pull-up node stable in a process of transmitting the boosted voltage of the pull-up node to the signal output terminal.

18. The driving method according to claim 16, wherein in a case where the shift register further comprises a pull-down node, an input sub-circuit, a reset sub-circuit, a node control sub-circuit, a first noise reduction sub-circuit and a second noise reduction sub-circuit,
the charging period further includes:
the input sub-circuit being turned on under the control of an input signal transmitted by a signal input terminal, to transmit a second voltage signal received at a second voltage terminal to the pull-up node; and
transmitting, by the node control sub-circuit, the first voltage signal received at the first voltage terminal to the pull-down node in response to the voltage of the pull-up node and the second voltage signal received at the second voltage terminal;
the driving method further comprises a resetting period after the outputting period, and the resetting period includes:
the reset sub-circuit being turned on under control of a reset signal transmitted by a reset signal terminal, to output the first voltage signal received at the first voltage terminal to the pull-up node;
transmitting, by the node control sub-circuit, the second voltage signal received at the second voltage terminal to the pull-down node in response to the voltage of the pull-up node and the second voltage signal received at the second voltage terminal;
the first noise reduction sub-circuit being turned on under the control of the voltage of the pull-down node, to transmit the first voltage signal received at the first voltage terminal to the pull-up node;
the second noise reduction sub-circuit being turned on under the control of the voltage of the pull-down node, to transmit the first voltage signal received at the first voltage terminal to the signal output terminal; and
the pull-down sub-circuit being turned on under the control of the second clock signal transmitted by the second clock signal terminal, to transmit the first voltage signal received at the first voltage terminal to the signal output terminal; and
the driving method further comprises a noise reduction period after the resetting period and before a next frame cycle, and the noise reduction period includes:
the second noise reduction sub-circuit being kept on under the control of the voltage of the pull-down node, to transmit the first voltage signal received at the first voltage terminal to the signal output terminal.
